(19) United States
(12) Patent Application Publication
(10) Pub. No.: US 2025/0273508 A1
(43) Pub. Date: Aug. 28, 2025

(54) DRIVE ASSEMBLIES, SEMICONDUCTOR PROCESSING SYSTEMS INCLUDING DRIVE ASSEMBLIES, AND RELATED METHODS OF DEPOSITING MATERIAL LAYERS IN SEMICONDUCTOR PROCESSING SYSTEMS USING DRIVE ASSEMBLIES

(71) Applicant: ASM IP Holding B.V., Almere (NL)

(72) Inventor: Frank Palmer, Phoenix, AZ (US)

(21) Appl. No.: 19/063,247

(22) Filed: Feb. 25, 2025

Related U.S. Application Data
(60) Provisional application No. 63/558,929, filed on Feb. 28, 2024.

(51) Int. Cl. H01L 21/687; G05B 19/418; H01F 7/02; H01L 21/67

(52) U.S. Cl. CPC H01L 21/68785; G05B 19/4188; H01F 7/0247; H01L 21/67259; G05B 2219/45031

(57) ABSTRACT

A drive assembly includes a shaft member, a shaft carrier, and a permanent magnet. The shaft member has a spider end and a drive end arranged along a rotation axis. The shaft carrier seats therein the drive end of the shaft member and is fixed in rotation about the rotation axis relative to the shaft member. The permanent magnet is seated in the shaft carrier, is fixed in rotation about the rotation axis relative to the shaft carrier and is axially offset from the spider end of the shaft member electromagnetically levitate and electromagnetically rotate a substrate support carried on the spider end of the shaft member. Semiconductor processing systems including drive assemblies and methods of depositing material layers onto substrates using drive assemblies are also described.

### CROSS-REFERENCE TO RELATED APPLICATION(S)

This Application claims the benefit of U.S. Provisional Application 63/558,929 filed on Feb. 28, 2024, the entire contents of which are incorporated herein by reference.

### FIELD OF INVENTION

The present disclosure generally relates to depositing material layers onto substrates, and more particularly to depositing material layers onto substrates during the fabrication of semiconductor devices.

### BACKGROUND OF THE DISCLOSURE

Material layers are commonly deposited onto substrates during the fabrication of semiconductor devices, such as during the fabrication of integrated circuit and power electronic semiconductor devices. Depositing may be accomplished by seating the substrate in a reactor on a substrate support, heating the substrate to a desired temperature, and exposing the substrate to a precursor under environmental conditions selected to cause a material layer to form onto the substrate. Once the material layer develops desired properties flow of the precursor typically ceases such that the substrate may be unseated from the substrate support and removed from the reactor for further processing, as appropriate for the semiconductor device being fabricated. In some reactors the substrate support may rotate during deposition of the material layer onto the substrate, for example using rotation communicated through a gear or transmission.

Such methods and systems have generally been considered suitable for their intended purpose. However, there remains a need in the art for improved drive assemblies, semiconductor processing systems including drive assemblies, and methods of depositing material layers onto substrates using semiconductor processing systems having drive assemblies. The present disclosure provides a solution to this need.

### SUMMARY OF THE DISCLOSURE

A drive assembly is provided. The drive assembly includes a shaft member, a shaft carrier, and a permanent magnet. The shaft member has a spider end and a drive end arranged along a rotation axis. The shaft carrier seats therein the drive end of the shaft member and is fixed in rotation about the rotation axis relative to the shaft member. The permanent magnet is seated in the shaft carrier, is fixed in rotation about the rotation axis relative to the shaft carrier, and is axially offset from the spider end of the shaft member to at least one of electromagnetically levitate a substrate support carried on the spider end along the rotation axis and electromagnetically rotate the substrate support carried on the spider end about the rotation axis.

In addition to one or more of the features described above, or as an alternative, further examples of the drive assembly may include that the shaft carrier has a first surface, a second surface, and intermediate surface. The first surface may extend about the rotation axis and define a shaft seat therein. The second surface may also extend about the rotation axis and be axially offset from the first surface in a direction opposite the shaft member. The intermediate surface may extend about the rotation axis and couple the first surface of the shaft carrier to the second surface of the shaft carrier. The second surface may axially tape along the rotation axis between a major radial width proximate the intermediate surface and a minor radial width axially opposite the first surface of the shaft carrier. The shaft carrier may be formed from a non-magnetic material such as a polymeric material or an aluminum-containing material.

In addition to one or more of the features described above, or as an alternative, further examples of the drive assembly may include that the permanent magnet is arranged axially between the first surface and the second surface of the shaft carrier to electromagnetically rotate the shaft carrier and therethrough the substrate support in rotation about the rotation axis.

In addition to one or more of the features described above, or as an alternative, further examples of the drive assembly may include that the permanent magnet is arranged axially between the major radial width and the minor radial width defined by the shaft carrier to electromagnetically levitate the shaft carrier and therethrough the substrate support along the rotation axis.

In addition to one or more of the features described above, or as an alternative, further examples of the drive assembly may include a sensor opposing the shaft carrier and configured to acquire at least one of axial position of the substrate support along the rotation axis and rotational position of the substrate support during rotation about the rotation axis.

In addition to one or more of the features described above, or as an alternative, further examples of the drive assembly may include a stator body extending about the shaft carrier. The stator body may be formed from a non-magnetic material, such as a polymeric material or an aluminum-containing material. The stator body may have a hollow interior terminating at a tapered recess. The stator body may receive the shaft carrier within the hollow interior of the stator body to electromagnetically levitated and rotate the shaft carrier within the hollow interior of the stator body.

In addition to one or more of the features described above, or as an alternative, further examples of the drive assembly may include that the stator body may have an inner recess conjugate to the second surface of the shaft carrier for landing the shaft carrier therein.

In addition to one or more of the features described above, or as an alternative, further examples of the drive assembly may include a plurality of windings. The plurality of windings may be distributed circumferentially about the rotation axis. The plurality of windings and the one or more permanent magnet inhabit a common axial position along the rotation axis.

In addition to one or more of the features described above, or as an alternative, further examples of the drive assembly may include that the plurality of windings are axially overlapped by the shaft carrier along the rotation axis.

In addition to one or more of the features described above, or as an alternative, further examples of the drive assembly may include the plurality of windings is at least one of (a) arranged in a grid and (b) distributed about a circumference overlayed by the shaft carrier along the rotation axis.

In addition to one or more of the features described above, or as an alternative, further examples of the drive assembly may include that the shaft member includes or is formed from a ceramic material. The ceramic material may include (e.g., consist of or consist essentially of) quartz, fused silicon or sapphire.

A semiconductor processing system is provided. The semiconductor processing system includes a chamber arrangement having a chamber body, a drive assembly as described above, a substrate support, and a controller. The chamber body has a hollow interior. The shaft member of the drive assembly extends into the chamber body such that the spider end of the shaft member is disposed within the interior of the chamber body. The substrate support is arranged within the interior of the chamber body and is fixed in rotation about the rotation axis relative to the shaft member of the drive assembly. The controller is operatively connected to the drive assembly and responsive to instructions record on a memory to electromagnetically levitate the substrate support within the interior of the chamber body and along the rotation axis using the drive assembly. The instructions recorded on the memory further cause the controller to electromagnetically rotate the substrate support within the interior of the chamber body and about the rotation axis using the drive assembly.

In addition to one or more of the features described above, or as an alternative, further examples of the semiconductor processing system may include that the permanent magnet is a first permanent magnet and that the semiconductor processing system further includes a second permanent magnet, a first plurality of windings, and a second plurality of windings. The first permanent magnet may be arranged axially between a first surface and a second surface of the shaft carrier. The second permanent magnet may be fixed in the shaft carrier and arranged axially between a major radial width and a minor radial width defined by the shaft carrier. The first plurality of windings may be radially offset from the shaft carrier and configured to electromagnetically exert a rotational force on the shaft carrier via the first permanent magnet. The second plurality of windings may be axially offset from the shaft carrier and configured to electromagnetically exert an axial force on the shaft carrier via the second permanent magnet. The instructions recorded on the memory may further cause the controller to electromagnetically rotate the substrate support about the rotation axis using the one or more first permanent magnet and a rotation current provided to the second plurality of windings, and electromagnetically levitate along the rotation axis the substrate support using the one or more second permanent magnet and a levitation current provided to the first plurality of windings.

In addition to one or more of the features described above, or as an alternative, further examples of the semiconductor processing system may include a sensor, such an optical sensor like an interferometer or a Hall effect sensor. The sensor may disposed in communication with the shaft carrier and configured to provide a signal to the controller indicative of at least one of an axial position and a rotational position of the substrate support within the chamber body.

In addition to one or more of the features described above, or as an alternative, further examples of the semiconductor processing system may include that the instructions further cause the controller to control at least one of axial position of the substrate support along the rotation axis and rotational speed of the substrate support about the rotation axis within the chamber body using the signal provided by the sensor.

In addition to one or more of the features described above, or as an alternative, further examples of the semiconductor processing system may include that the instructions further cause the controller to control at least one of runout and wobble of the substrate support within the chamber body during rotation about the rotation axis using the signal provided by the sensor.

A material layer deposition method is provided. The method includes, at semiconductor processing system including a drive assembly as described above, seating a substrate on the substrate support, and while at least one of electromagnetically levitating the substrate support and electromagnetically rotating the substrate support using the permanent magnet and a plurality of windings electromagnetically coupled to the permanent magnet, heating the substrate to a predetermined material layer deposition temperature; exposing the substrate to a material layer precursor; and depositing a material layer onto the substrate using the material layer precursor.

In addition to one or more of the features described above, or as an alternative, further examples of the material layer deposition method may include determining axial position of the substrate support along the rotation axis during rotation about the rotation axis; comparing the determined axial position to a predetermined axial position; and adjusting axial height of the substrate support when the determined axial position differs from the predetermined axial position by more than a predetermined amount during deposition of the material layer onto the substrate.

In addition to one or more of the features described above, or as an alternative, further examples of the material layer deposition method may include determining rotational speed of the substrate support about the rotation axis during rotation about the rotation axis; comparing the determined rotational speed of the substrate support to a predetermined rotational speed; and adjusting rotational speed of the substrate support when the determined rotational speed differs from the predetermined rotational speed by more than a predetermined amount during deposition of the material layer onto the substrate.

In addition to one or more of the features described above, or as an alternative, further examples of the material layer deposition method may include determining runout of the substrate support about the rotation axis during rotation about the rotation axis; comparing the determined runout of the substrate support to a predetermined runout value; and adjusting runout of the substrate support when the determined runout differs from the predetermined runout value by more than a predetermined amount during deposition of the material layer onto the substrate.

In addition to one or more of the features described above, or as an alternative, further examples of the material layer deposition method may include determining wobble of the substrate support about the rotation axis during rotation about the rotation axis; comparing the determined wobble of the substrate support to a predetermined wobble value; and adjusting wobble of the substrate support when the determined wobble differs from the predetermined wobble value by more than a predetermined amount during deposition of the material layer onto the substrate.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system in accordance with the present disclosure, showing a substrate support being electromagnetically levitated and rotated by a drive assembly during deposition of a material layer onto the substrate;

FIG. 2 is a cross-sectional side view of a portion of the semiconductor processing system of FIG. 1 according to an example of the disclosure, showing the chamber arrangement and a controller of the semiconductor processing system;

FIGS. 3 and 4 are side elevation and exploded views of the drive assembly of FIG. 1 to an example of the disclosure, showing a shaft carrier seating a shaft member and permanent magnets for electromagnetic coupling with a first and second winding array;

FIG. 5 is a plan view of a portion of the drive assembly is an exploded view of the drive assembly of FIG. 3 according to an example of the disclosure, schematically the first and second winding arrays operatively connected to a power source by the controller; and

FIGS. 6-10 are a block diagram of a material layer deposition method according to the present disclosure, showing operations of the method according to an illustrative and non-limiting example of the method.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

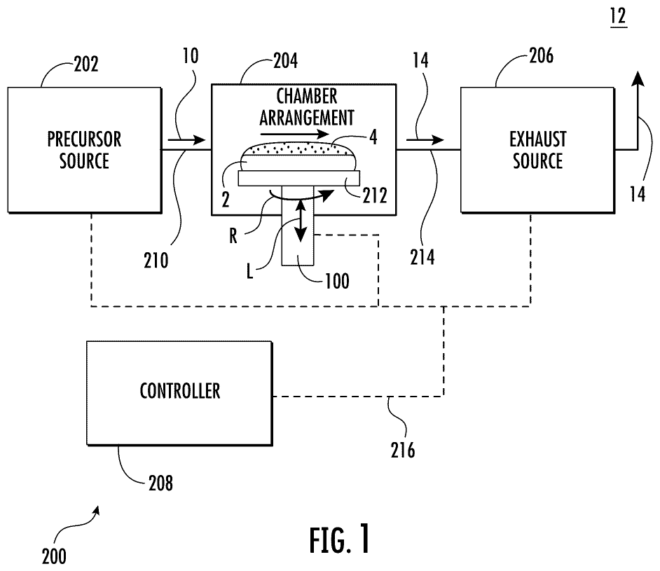

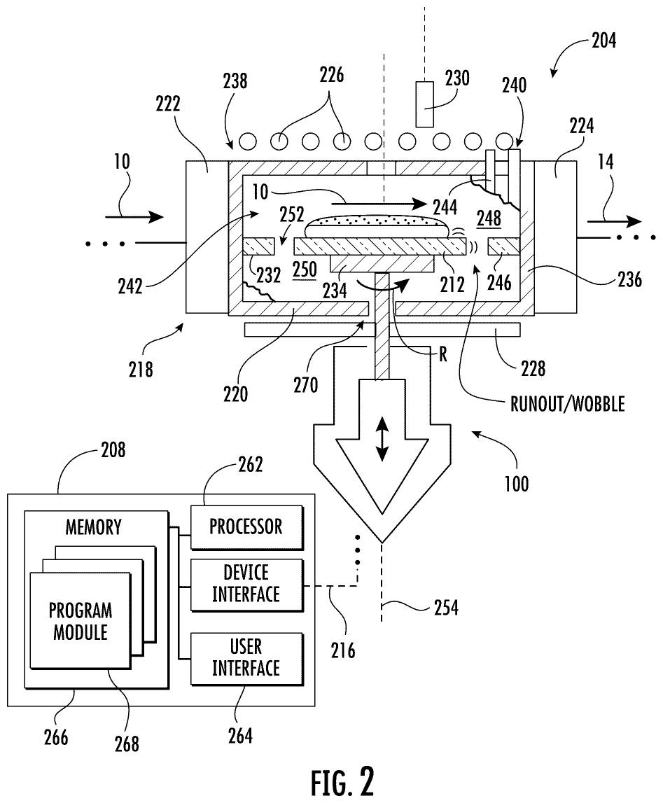

Reference will now be made to the drawings wherein like reference numerals identify similar structural features or aspects of the subject disclosure. For purposes of explanation and illustration, and not limitation, a partial view of a semiconductor processing system including a drive assembly in accordance with the present disclosure is shown in FIG. 1 and is designated generally by reference character 100. Other examples of semiconductor processing systems, drive assembles, and methods of depositing material layers onto substrates in accordance with the present disclosure, or aspects thereof, are provided in FIGS. 2-10, as will be described. The systems and methods of the present disclosure may be used to deposit material layers onto substrates using chemical vapor deposition (CVD) techniques, such as silicon-containing epitaxial material layers during the fabrication of semiconductor devices, though the present disclosure is not limited any particular material layer nor to CVD deposition techniques in general.

Referring to FIG. 1, a semiconductor processing system 200 including the drive assembly 100 is shown. The semiconductor processing system 200 includes a precursor source 202, a chamber arrangement 204 including the drive assembly 100, an exhaust source 206, and a controller 208. The precursor source 202 is coupled to the chamber arrangement 204 by a precursor supply conduit 210, includes a material layer precursor 10, and is configured to communicate a flow of the material layer precursor 10 to the chamber arrangement 204. The chamber arrangement 204 includes a substrate support 212, is coupled to the exhaust source 206 by an exhaust conduit 214, and is configured to expose a substrate 2 seated on the substrate support 212 to the material layer precursor 10 under environmental conditions (e.g., pressure and/or temperature) selected to cause a material layer 4 to deposit onto the substrate 2 while the substrate 2 is electromagnetically levitated and rotated using the drive assembly 100. The exhaust source 206 is in communication with an external environment 12 outside of the semiconductor processing system 200 and is configured to communicate a flow of residual precursor and/or reaction products 14 issued by the chamber arrangement 204 during deposition of the material layer 4 onto the substrate 2, for example using a vacuum pump and an abatement device like a scrubber. The controller 208 is operably connected to one or more element of the semiconductor processing system 200, e.g., the drive assembly 100 to control electromagnetic levitation and/or rotation R of the substrate support 212 during deposition of the material layer 4 onto the substrate 2 and is this respect may be coupled thereto by a wired or wireless link 216.

In certain examples, the precursor source 202 may be configured to communicate one or more silicon-containing material layer precursor within the material layer precursor 10 communicated to the chamber arrangement 204. Examples of suitable material layer precursors include non-chlorinated silicon-containing material layer precursors such as silane (SiH₄) and disilane (Si₂H₆) as well as chlorinated silicon material layer precursors like dichlorosilane (H₂SiCl₂) and trichlorosilane (HCl₃Si). In accordance with certain examples, the precursor source 202 may be configured to communicate a dopant-containing material layer precursor and/or an alloying constituent within the material layer precursor 10 to the chamber arrangement 204. Examples of suitable dopant-containing material layer precursors include n-type dopant-containing material layer precursors, such as compounds containing phosphorous (P) or arsine (As), as well as n-type dopant-containing material layer precursors like compounds containing boron (B); examples of suitable alloying constituents include germanium-containing compounds, such as germane (GeH₄) by way of non-limiting example.

It is contemplated that the precursor source 202 may be configured to communicate an etchant to the chamber arrangement 204, which may be co-flowed with the material layer precursor or provided as a separate flow to the chamber arrangement 204. Examples of suitable etchants include halogen-containing compounds such as hydrochloric (HCl) acid and chlorine (Cl₂) gas as well as fluorine-containing compounds like hydrofluoric (HF) acid. It is also contemplated that the precursor source may be configured to communicate a diluent or carrier fluid (e.g., a gas) to the chamber arrangement 204. For example, the precursor source 202 may be configured to communicate one or more of hydrogen (H₂) gas, nitrogen (N₂) gas, a noble gases, or a mixtures including one or more of the aforementioned gases. The carrier or diluent fluid may be communicated to the chamber arrangement with the material layer precursor 10 or separately, such as a purge fluid flow.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates may be made from semiconductor materials, including, for example, silicon (Si), silicon germanium (SiGe), silicon oxide (SiO₂), gallium arsenide (GaAs), gallium nitride (GaN) and silicon carbide (SiC). As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

With reference to FIG. 2, the chamber arrangement 204 and the controller 208 are shown according to an example of the present disclosure. In the illustrated example the chamber arrangement 204 has a single-wafer crossflow architecture 218 and includes a chamber body 220, an injection flange 222, an exhaust flange 224, an upper heater element array 226, a lower heater element array 228, and a pyrometer 230. In the illustrated example the chamber arrangement 204 also includes a divider 232, the substrate support 212, a spider member 234, and the drive assembly 100. Although shown and described herein as having a specific arrangement and architecture it is to be understood and appreciated that the chamber arrangement 204 may have a different arrangement in other examples, for example a multi-wafer crossflow arrangement (e.g., a minibatch architecture), and remain within the scope of the present disclosure.

The chamber body 220 is formed from a ceramic material 236, extends between an injection end 238 and a longitudinally opposite exhaust end 240, and defines a process space within an interior 242 of the chamber body 220. The injection flange 222 abuts the injection end 238 of the chamber body 220 and fluidly couples the precursor source 202 (shown in FIG. 1) to the process space within the interior 242 of the chamber body 220. The exhaust flange 224 abuts the exhaust end 240 of the chamber body 220 and fluidly couples the process space within the interior 242 of the chamber body 220 to the exhaust source 206 (shown in FIG. 1). In certain examples, the ceramic material 236 may be a transparent material, such as a material transparent to electromagnetic radiation within an infrared waveband like quartz or sapphire. In accordance with certain examples, the chamber body 220 may have a plurality of external ribs 244. In such examples the external ribs 244 may extend laterally about an exterior surface of the chamber body 220. In such examples the external ribs 244 may further be longitudinally spaced apart from one another between the injection end 238 and the exhaust end 240 of the chamber body 220. It is contemplated that the injection flange 222 may be as shown and described in U.S. Pat. No. 11,053,591 to Ma et al., filed Aug. 6, 2018, the contents of which is incorporated herein by reference in its entirety. It is also contemplated that the exhaust flange 224 may be as shown and described in U.S. Pat. No. 10,612,136 to Sreeram et al., filed on Jun. 29, 2018, the contents of which are incorporated herein by reference in its entirety.

The upper heater element array 226 is supported above the chamber body 220 and is configured to communicate heat into the interior 242 of the chamber body 220, for example radiantly using electromagnetic radiation having one or more wavelength within an infrared waveband transmitted in the interior 242 of the chamber body 220 by the ceramic material 236 forming the chamber body 220. In certain examples, the upper heater element array 226 may include a plurality of filament-type heater elements, such as linear lamps extending laterally above the chamber body 220 and longitudinally spaced apart from one another between the injection end 238 and the exhaust end 240 of the chamber body 220. In accordance with certain examples, the upper heater element array 226 may include one or more bulb-type heater element supported above the chamber body 220. It is contemplated that the lower heater element array 228 be similar to the upper heater element array 226 and additionally be supported below the chamber body 220. The pyrometer 230 may be supported above the chamber body 220 and configured to control communication of heat into the interior 242 of the chamber body 220, for example through operable coupling to either (or both) the upper heater element array 226 and the lower heater element array 228 through the controller 208.

The divider 232 is formed from an opaque material 246, e.g., a material opaque to electromagnetic radiation within an infrared waveband and is seated within the interior 242 of the chamber body 220. The divider 232 may further divide the interior 242 of the chamber body 220 into an upper chamber 248 (which may in whole or in part include the process space) and a lower chamber 250. It is contemplated that the divider 232 further define a divider aperture 252 therethrough, and that the divider aperture 252 fluidly couple the upper chamber 248 to the lower chamber 250. In certain examples the opaque material 246 may include a ceramic material, such as silicon carbide in coating or bulk form. In accordance with certain examples, the opaque material 246 may include a bulk carbonaceous material, such as pyrolytic carbon or graphite. It is also contemplated that the opaque material 246 may include a combination of the aforementioned materials and remain within the scope of the present disclosure.

The substrate support 212 may be formed from an opaque material (e.g., the opaque material 246) and is arranged within the interior 242 of the chamber body 220. In this respect it is contemplated that the substrate support 212 be supported within the divider aperture 252 and along a rotation axis 254 and is operably associated with the drive assembly 100. Operable coupling may be via the spider member 234, which may be formed from a ceramic (e.g., the ceramic material 236) and arranged along the rotation axis 254. The spider member 234 may further be arranged within the lower chamber 250, be fixed in rotation R relative to the substrate support 212 in rotation about the rotation axis 254 and couple the substrate support 212 to the drive assembly 100. In certain examples, substrate support 212 may include a susceptor body. In accordance with certain examples, the chamber arrangement 204 may further include a plurality of lift pins slidably received within the substrate support 212, which may cooperate with a lift pin actuator as well as a gate valve and a substrate transfer robot for seating and unseating substrates, e.g., the substrate 2, from the substrate support 212. Examples of suitable lift pins and lift pin actuators include those shown and described in co-pending U.S. patent application Ser. No. 18/397,372 to Evans et al., filed on Dec. 27, 2023, the contents of which are incorporated herein by reference in its entirety.

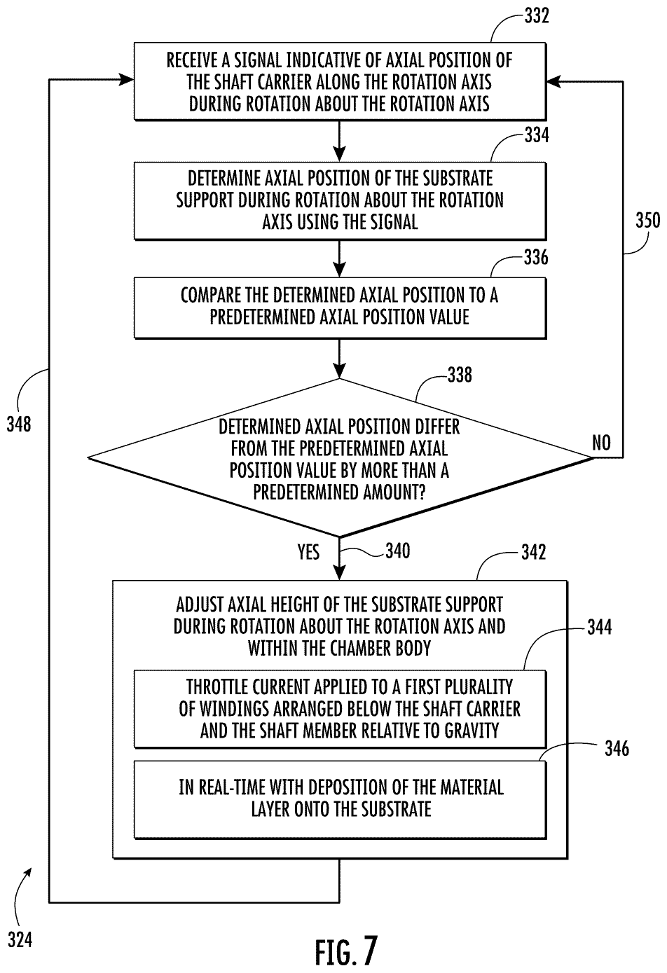

The controller 208 may be configured to control electromagnetic levitate L and rotate R the substrate support 212 within the chamber body 220 using the drive assembly 100 and in this respect may include a device interface 260, a processor 262, a user interface 264, and a memory 266. The device interface 260 may couple the controller 208 to the drive assembly 100 via the wired or wireless link 216 and/or other elements of the semiconductor processing system 200 (shown in FIG. 1), is coupled to the processor 262. The processor 262 is coupled to the device interface 260, is operably coupled to the user interface 264 to receive user input and/or provide user output therethrough and is disposed in communication with the memory 266. The memory 266 includes a non-transitory machine-readable medium having a plurality of program modules 268 recorded thereon containing instructions that, when read by the processor 262, cause the processor 262 execute certain operations. Among the operations are operations of a material layer deposition method 300 (shown in FIG. 7), as will be described. Although shown and described herein as having a specific architecture, it is to be understood and appreciated that the controller 208 can have different architectures in other examples of the present disclosure (e.g., a distributed computing architecture), and remain within the scope of the present disclosure.

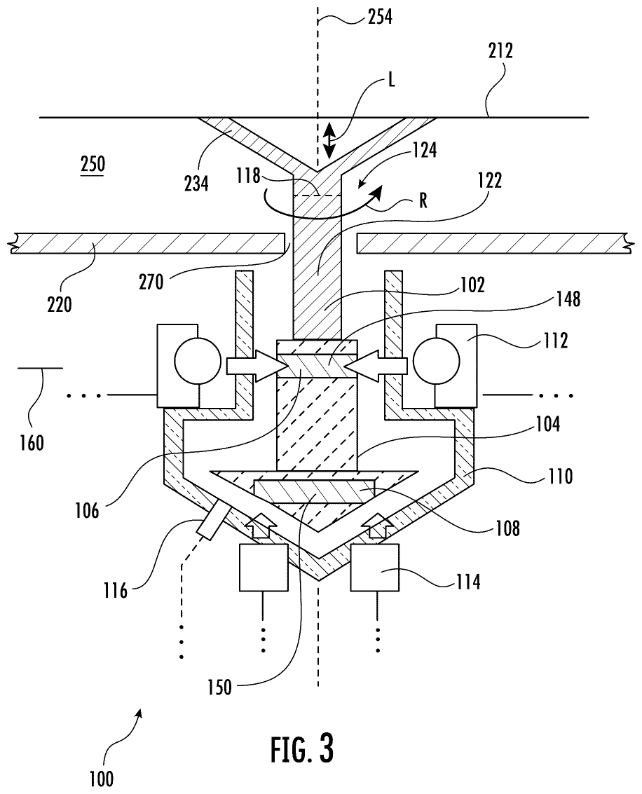

With reference to FIGS. 3-5, the drive assembly 100 is shown according to an example of the present disclosure. As shown in FIG. 3, the drive assembly 100 may be configured to at least one of electromagnetically levitate L and electromagnetically rotate R the substrate support 212 within the chamber body 220 (shown in FIG. 1) and in this respect may include a shaft member 102, a shaft carrier 104, one or more first permanent magnet 106, and one or more second permanent magnet 108. In the illustrated example the drive assembly 100 also includes a stator body 110, a first plurality of windings 112, a second plurality of windings 114, and a sensor 116. Although shown and described herein as having certain elements and a particular arrangement, it is to be understood and appreciated that the drive assembly 100 may include additional elements and/or omit elements shown and described herein, and/or have an arrangement differing from that shown and described herein and remain within the scope of the present disclosure.

The shaft member 102 may be formed from a ceramic material 122 and has a spider end 124 and a drive end 126 arranged along the rotation axis 254. It is contemplated that, when assembled into the chamber arrangement 204 (shown in FIG. 2), the spider end 124 of the shaft member 102 may be disposed within the lower chamber 250 of the chamber body 220, and that the drive end 126 may be supported below the chamber body 220 at a location below the chamber body 220. The drive end 126 of the shaft member 102 may be further axially offset from the spider end 124 along the rotation axis 254. The spider end 124 of the shaft member 102 may be configured to carry the substrate support 212 (e.g., via the spider member 234 such that the shaft member 102 is fixed in rotation R relative to the substrate support 212 about the rotation axis 254. In certain examples, the ceramic material 122 forming the shaft member 102 may include a transparent material, e.g., a material transparent to electromagnetic radiation within an infrared waveband, such as quartz or sapphire. In accordance with certain examples, the shaft member 102 may consist of (or consist essentially of) the ceramic material 122. As will be appreciated by those of skill in the art in view of the present disclosure, forming the shaft member 102 from a material transparent to electromagnetic radiation within an infrared waveband may improve uniformity of the material layer 4 (shown in FIG. 1) deposited onto the substrate 2 (shown in FIG. 1), for example by simplifying temperature control of the substrate support 212 and therethrough the substrate 2.

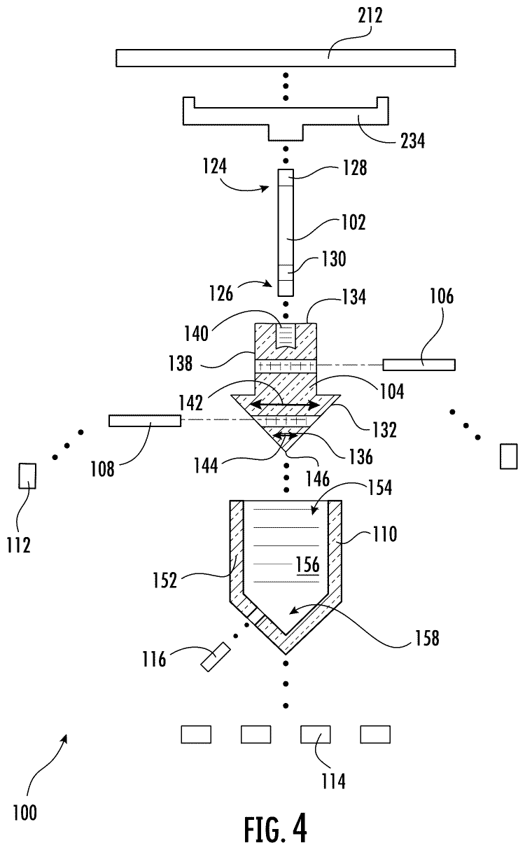

In certain examples the spider end 124 of the shaft member 102 may have a shaft coupling 128 (shown in FIG. 4). The shaft coupling 128 in such examples may be configured to carry the spider member 234 and therethrough the substrate support 212. In this respect the shaft coupling 128 may removably seat thereon the spider member 234 and therethrough the substrate support 212. As will be appreciated by those of skill in the art in view of the present disclosure, inclusion of the shaft coupling 128 of the spider end 124 of the shaft member 102 enables removable seating of the spider member 234 on the spider end 124 of the shaft member 102. Advantageously, removably seating the spider member 234 on the spider end 124 of the shaft member 102 in turn may limit variation of properties of the material layer 4 (shown in FIG. 1) deposited onto the substrate 2, for example by enabling the process volume defined within the upper chamber 248 (shown in FIG. 1) of the chamber body 220 (shown in FIG. 2) to be relatively small and/or promote laminar flow of the material layer precursor 10 (shown in FIG. 1) therethrough.

In certain examples the spider member 234 may be inseparably fixed to the spider end 124 of the shaft member 102, for example at a fused joint or weld 118. In such examples the shaft member 102 the substrate support 212 and the spider member 234 may be non-severable from one another. As will also be appreciated by those of skill in the art in view of the present disclosure, inseparably fixing the spider member 234 to the spider end 124 of the shaft member 102 may simplify assembly of the chamber arrangement 204, for example by eliminating the need to form a shaft coupling on the shaft member 102 with geometry selected to enable repeatability in position of the spider member 234 on the shaft member 102 within interior 242 (shown in FIG. 2) of the chamber body 220.

As shown in FIG. 4, the drive end 126 of the shaft member 102 is configured for seating in the shaft carrier 104 and in this respect may define an anti-rotation feature 130. In certain examples, the anti-rotation feature 130 may include a spline or groove. In accordance with certain examples, the anti-rotation feature 130 may include a through-hole. In such examples the shaft carrier 104 may define therein a corresponding spline or be configured to receive therein a corresponding fastener to fix the shaft carrier 104 relative to the shaft member 102 in rotation about the rotation axis 254. As will be appreciated by those of skill in the art, the anti-rotation feature 130 enables seating the shaft member 102 in the shaft carrier 104 prior to registering the shaft carrier 104 to a passthrough 270 (shown in FIG. 2) defined with the chamber body 220 (shown in FIG. 2), facilitating assembly of the chamber arrangement 204 (shown in FIG. 1).

The shaft carrier 104 may be formed from a magnetically permeable material 132 and configured to receive therein the drive end 126 of the shaft member 102 such that the shaft carrier 104 is fixed in rotation R relative to the shaft member 102 about the rotation axis 254 (shown in FIG. 2). The shaft carrier 104 may further be configured for fixation relative to shaft member 102 and therethrough the spider member 234 and the substrate support 212 (shown in FIG. 1) in rotation R about the rotation axis 254. In certain examples, the shaft carrier 104 may have a first surface 134, a second surface 136, and an intermediate surface 138. In such examples the first surface 134 may extend about the rotation axis 254 and define a shaft seat 140 therein configured to receive therein the drive end 126 of the shaft member 102. The second surface 136 may also extend about the rotation axis 254, additionally be axially offset from the first surface 134, and further be axially spaced apart from the first surface 134 of the shaft carrier 104. The intermediate surface 138 may extend about the rotation axis 254, additionally couple the second surface 136 to the first surface 134, and further be substantially parallel to the rotation axis 254.

In certain examples the second surface 136 of the shaft carrier 104 may taper axially in radial width along the rotation axis 254 and in a direction opposite the shaft member 102. In this respect the second surface 136 may define a major radial width 142 proximate the first surface 134 and a minor radial width 144 distal to the first surface 134 of the shaft carrier 104. The major radial width 142 of the second surface 136 may be greater than the minor radial width 144 of the second surface 136. The minor radial width 144 may in turn be axially separated from the first surface 134 of the shaft carrier 104, for example by either (or both) the major radial width 142 and the intermediate surface 138 of the shaft carrier 104. In accordance with certain examples, the second surface 136 of the shaft carrier 104 may terminate at a tip 146. The tip 146 may be arranged along the rotation axis 254 and, in certain examples, intersect the rotation axis 254. Advantageously, the taper of the second surface 136 may enable self-centering of the shaft carrier 104 within the stator body 110, for example during service events during which the shaft carrier 104 may be landed within a hollow interior 156 of the stator body 110, the shaft carrier 104 and the stator body 110 there cooperating to facilitate removal and replacement of the substrate support 212 from the drive assembly 100.

With continuing reference to FIG. 4, the one or more first permanent magnet 106 is formed from a magnetic material 148 and seated in the shaft carrier 104. The one or more first permanent magnet 106 may be further fixed in rotation R about the rotation axis 254 relative to the shaft carrier 104. It is contemplated that the one or more first permanent magnet 106 may be axially offset from the spider end 124 of the shaft member 102 and/or radially offset from the rotation axis 254, the one or more first permanent magnet 106 thereby configured to electromagnetically rotate the substrate support 212 carried on the spider end 124 of the shaft member 102 about the rotation axis 254 in cooperation with the first plurality of windings 112. In certain examples, the one or more first permanent magnet 106 may be arranged axially between the first surface 134 and the second surface 136 of the shaft carrier 104 to electromagnetically rotate the shaft carrier 104 (and therethrough the substrate support 212 via the shaft member 102) about the rotation axis 254. In further respect, the one or more first permanent magnet 106 may be one of a plurality of first permanent magnets 106 distributed circumferentially about the rotation axis 254 to drive the shaft carrier 104 and therethrough the substrate support 212 about the rotation axis 254. In certain examples the magnetic material 148 forming the one or more first permanent magnet 106 may include a rare-earth element, such as neodymium or a samarium-cobalt composition by way of non-limiting example. As will be appreciated by those of skill in the art in view of the present disclosure, forming the one or more first permanent magnet 106 from a rare-earth element imparts relatively high remanence to the one or more first permanent magnet 106 relative to the mass of the one or more first permanent magnet 106, enabling the drive assembly 100 to have a lower center of gravity than otherwise possible.

The one or more second permanent magnet 108 may be formed from a magnetic material 150 and seated in the shaft carrier 104. The one or more second permanent magnet 108 may further be fixed in rotation R about the rotation axis 254 relative to the shaft carrier 104 to electromagnetically levitate the substrate support 212 carried by the spider end 124 of the shaft member 102 along the rotation axis 254. The one or more second permanent magnet 108 may further be separated from the spider end 124 of the shaft member 102 by the one or more first permanent magnet 106, the one or more second permanent magnet 108 proximate the tip 146 of the shaft carrier 104 in certain examples of the present disclosure. In certain examples, the one or more second permanent magnet 108 may be arranged axially between the major radial width 142 and the minor radial with 144 defined by the second surface 136 of the shaft carrier 104, for example at a location whereat the second surface 136 radially overlaps the one or more second permanent magnet 108, to axially levitate the shaft carrier 104 (and therethrough substrate support 212 via the shaft member 102) along the rotation axis 254 in cooperation with the second plurality of windings 114. In this respect the one or more second permanent magnet 108 may be arranged along the rotation axis 254, for example such that the rotation axis 254 intersects the one or more second permanent magnet 108. In certain examples, the magnetic material 150 may have a composition substantially identical to that of the magnetic material 148. In accordance with certain examples, the magnetic material 150 may have a composition differing from that of the magnetic material 150, for example a material having a lower remanence than that of the magnetic material 148, such as a ferromagnetic material. As will be appreciated by those of skill in the art in view of the present, this can also enable the drive assembly 100 to have a relative low center of gravity.

Referring again to FIG. 4, the stator body 110 may be formed from a magnetically permeable material 152 and configured for fixation relative to the chamber body 220 (shown in FIG. 2) along the rotation axis 254, for example at a location in registration with the passthrough 270 (shown in FIG. 2). In this respect the stator body 110 may extend about the shaft carrier 104 and rotation axis 254, the stator body 110 radially overlapping (at least in part) the shaft carrier 104. The stator body 110 may further be configured to receive therein (at least in part) the shaft carrier 104 and may support either (or both) the first plurality of windings 112 and the second plurality of windings 114. In this respect it is contemplated that the stator body 110 have an opening 154 and a hollow interior 156 terminating at a tapered recess 158. The opening 154 opposes the chamber body 220, is sized to receive therethrough the shaft carrier 104, and is in communication with the hollow interior 156. The hollow interior 156 in turn extends about the rotation axis 254 and terminates at a tapered recess 158. The tapered recess 158 may be conjugate in shape to the second surface 136 of the shaft carrier 104, the stator body 110 thereby configured to land the shaft carrier 104 therein in an orientation wherein the tip 146 of the shaft carrier 104 and the shaft member 102 are coaxial with the rotation axis 254. As will be appreciated by those of skill in the art in view of the present disclosure, this can limit (or prevent entirely) risk of contact between the substrate support 212 and divider 232 (shown in FIG. 2) when the shaft carrier 104 is landed within the stator body 110 (or vice versa). In certain examples, the magnetically permeable material 152 may include a non-magnetic material, such as a polymeric material or an aluminum-containing material. As will also be appreciated by those of skill in the art in view of the present disclosure, forming the stator body 110 from such material may simplify fabrication of the drive assembly 100 as well simplify electromagnetic coupling of the first plurality of windings 112 and the second plurality of windings 114 with the one or more first permanent magnet 106 and the one or more second permanent magnet 108, respectively.

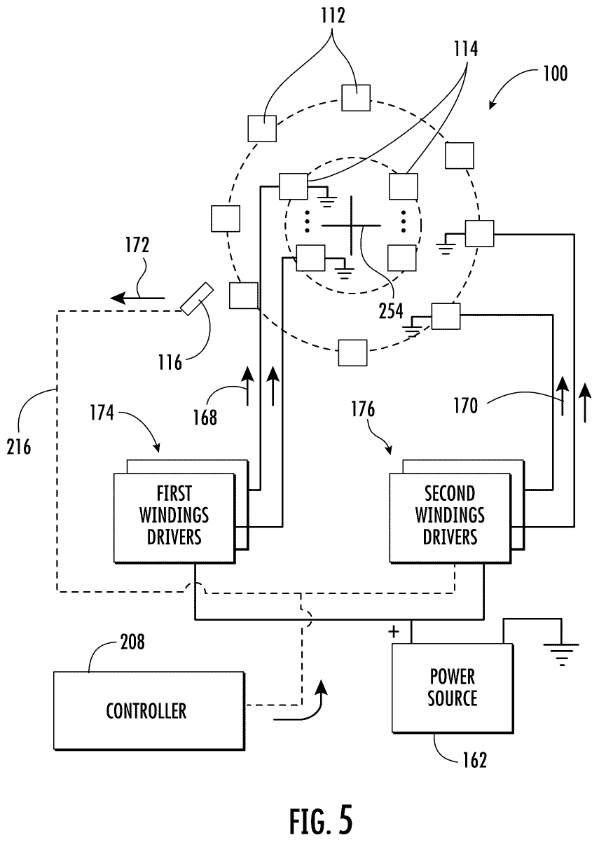

As shown in FIG. 5, the first plurality of windings 112 may be configured to electromagnetically rotate the shaft carrier 104 (and therethrough the substrate support 212 via the shaft member 102) about the rotation axis 254 and may be distributed circumferentially about the rotation axis 254. In certain examples, the first plurality of windings 112 and the one or more first permanent magnet 106 may inhabit a common axial position 160, the first plurality of windings 112 radially overlapping the one or more first permanent magnet 106 in such examples. In accordance with certain examples, the first plurality of windings 112 may be radially offset from the shaft carrier 104 and configured to exert a rotational force (e.g., a torque) on the shaft carrier 104 via the one or more first permanent magnet 106. It is contemplated that the first plurality of windings 112 further be electrically connected to a power source 162, and that the power source 162 in turn be configured to provide a rotation current 168 to the first plurality of windings 112 to electromagnetically rotate the shaft carrier 104 and therethrough the substrate support 212 about the rotation axis 254 at a predetermined rotational speed. In certain examples, connectivity of the first plurality of windings 112 to the power source 162 may be through the controller 208, the controller 208 in turn configured to throttle the flow of the rotation current 168 through the first plurality of windings 112 to control rotational speed of the substrate support 212 about the rotation axis 254.

In certain examples connectivity of the first plurality of windings 112 to the power source 162 through the controller 208 may be apportioned (e.g., individually controllable). For example, the controller 208 may operably couple the power source 162 to individual windings of the first plurality of windings 112 through a plurality of first winding current drivers 174, the controller 208 thereby configured to control either (or both) runout and wobble of the substrate support 212 within the divider aperture 252 (shown in FIG. 2) by individually throttling flows of the rotation current 168 to individual windings of the first plurality of windings 112 during rotation of the substrate support 212 about the rotation axis 254. Advantageously, throttling individual flows of the rotation current 168 to individual windings of the first plurality of windings 112 enables compensation for runout and wobble of the substrate support 212, for example using a feedforward generated from a characterization of runout and wobble of the substrate support 212 during rotation R within the chamber body 220 in a nominal (e.g., as-built) condition. As will be appreciated by those of skill in the art in view of the present disclosure, compensation for runout and wobble using the first plurality of windings 112 enables loosening the tolerance of seating features formed on the substrate support 212 (shown in FIG. 1) and/or the spider member 234, simplifying fabrication and substrate support 212 and/or the spider member 234 as well as assembly of the chamber arrangement 204.

The second plurality of windings 114 are configured to electromagnetically levitate the shaft carrier 104 (and therethrough the substrate support 212 via the shaft member 102) along the rotation axis 254. In this respect the second plurality of windings 114 maybe axially overlapped by the shaft carrier 104, for example such that the shaft carrier 104 axially separates the second plurality of windings 114 from the chamber body 220 (shown in FIG. 2). In certain examples, the second plurality of windings 114 may be arranged in a grid 164 intersecting the rotation axis 254, which maybe planar and substantially orthogonal relative to the rotation axis 254. In accordance with certain examples, the second plurality of windings 114 may be distributed of a circumference 166 extending about the rotation axis 254 at a location axially whereat the shaft carrier 104 axially overlaps the second plurality of windings 114. It is also contemplated that, in accordance with certain examples, the plurality of windings 114 may be arranged in a grid 164 overlapped by the shaft carrier 104 wherein a group of the second plurality of windings 114 are arranged circumferentially about the rotation axis 254.

The second plurality of windings 114 may be electrically connected to the power source 162. The power source 162 in turn may be configured to provide a levitation current 170 to the first plurality of windings 112 to electromagnetically levitate the shaft carrier 104 and therethrough the substrate support 212 along the rotation axis 254. In certain examples, connectivity of the second plurality of windings 114 to the power source 162 may be through the controller 208, the controller 208 in turn be configured to throttle the flow of the levitation current 170 through the second plurality of windings 114 to control axial position of the substrate support 212 along the rotation axis 254 and within the interior 242 (shown in FIG. 2) of the chamber body 220 (shown in FIG. 2). In accordance with certain examples, connectivity of the second plurality of windings 114 to the power source 162 through the controller 208 may be apportioned (e.g., individually controllable), the controller 208 operably coupling the power source 162 individually to individual windings of the second plurality of windings 114 through a plurality of second winding current drivers 176 and thereby configured to control either (or both) runout and wobble of the substrate support 212 within the divider aperture 252 (shown in FIG. 2) by throttling flows of the levitation current 170 to individual windings of the second plurality of windings 114. Advantageously, this enables both electromagnetic levitation of the shaft carrier 104 as well as runout and/or wobble compensation (or correction) of the substrate support 212 during rotation about the rotation axis 254 and within the interior 242 (shown in FIG. 2) of the chamber body 220 (shown in FIG. 2).

Referring once again to FIG. 3 and with continuing reference to FIG. 5, the sensor 116 may oppose the shaft carrier 104 and be configured to generate a signal 172 containing information indicative of at least one of axial position of the shaft carrier 104 along the rotation axis 254 and rotational position of the shaft carrier 104 about the rotation axis 254 during rotation R of the shaft carrier 104 about the rotation axis 254. In this respect the sensor 116 may be seated in the stator body 110. In further respect, the sensor 116 may be seated in the stator body 110 such that the second surface 136 of the shaft carrier 104 is within the field of view of the sensor 116. The sensor 116 may be disposed in communication with the controller 208, for example through the wired or wireless link 216, to provide the signal 172 to the controller 208. In certain examples, the sensor 116 may include an optical sensing device, such as an interferometer. In accordance with certain examples, the sensor 116 may include an electrical sensing device, such as a Hall effect sensor. It is also contemplated the sensor 116 may be configured to include in the signal 172 information indicating runout and/or wobble of the shaft carrier 104, and therethrough the substrate support 212, during rotation R about the rotation axis 254.

The controller 208 may be operably connected to the drive assembly 100 and responsive to instructions included in the plurality of program modules 268 (shown in FIG. 2) recorded on the memory 266 (shown in FIG. 2) to rotate the substrate support 212 within the interior 242 (shown in FIG. 2) of the chamber body 220 (shown in FIG. 2) and about the rotation axis 254 using the drive assembly 100. In this respect it is contemplated that the controller 208 may control flow the rotation current 168 to the first plurality of windings 112 to cause the shaft carrier 104, and therethrough the substrate support 212 via the shaft member 102 and spider member 234, to rotate about the rotation axis 254. The instructions may further cause the controller 208 to levitate the substrate support 212 within the interior 242 of the chamber body 220 and along the rotation axis 254 using the drive assembly 100. In this further respect the controller 208 may control flow of the levitation current 170 to the second plurality of windings 114 to levitate the shaft carrier 104, and therethrough the substrate support 212 via the shaft member 102 and the spider member 234, along the rotation axis 254.

In certain examples, the controller 208 may receive from the sensor 116 the signal 172. In such examples the signal 172 may contain information indicative of at least one of axial position of the substrate support 212 along the rotation axis 254 during rotation R of the substrate support 212 about the rotation axis 254 and rotational position of the substrate support 212 about the rotation axis 254 during rotation R of the substrate support 212 about the rotation axis 254. It is contemplated that the controller 208 may control either (or both) axial position of the substrate support 212 along the rotation axis 254 during rotation about the rotation axis 254 and rotational position (e.g., speed, acceleration, and deceleration) using the signal 172. In this respect the controller 208 may receive a predetermined rotation speed of the substrate support 212 about the rotation axis 254, determine rotational speed of the substrate support 212 about the rotation axis 254 within the interior 242 (shown in FIG. 2) of the chamber body 220 (shown in FIG. 2) using the signal 172, and increase (or decrease) the rotation current 168 provided to the first plurality of windings 112 when the determined rotational speed of the substrate support 212 about the rotation axis 254 differs from the predetermined rotational speed by more than a predetermined amount. In further respect, the controller 208 may receive a predetermined axial position of the substrate support 212 along the rotation axis 254, determine axial position of the substrate support 212 along the rotation axis 254 and within the interior 242 of the chamber body 220 using the signal 172, and increase (or decrease) the levitation current 170 provided to the second plurality of windings 114 when the determined axial position of the substrate support 212 along the rotation axis 254 differs from the predetermined axial position by more than a predetermined amount.

In certain examples the signal 172 may contain information indicative of at least one of runout (e.g., axial runout and/or radial runout) of the substrate support 212 wobble during rotation R of the substrate support 212 about the rotation axis 254 within the interior 242 (shown in FIG. 2) of the chamber body 220 (shown in FIG. 2). It is contemplated that the controller 208 may control either (or both) runout and wobble the substrate support 212 during rotation R about the rotation axis 254 within the chamber body 220 using the signal 172. In this respect the controller 208 may receive a predetermined runout characterization of the substrate support 212 about the rotation axis 254 (e.g., runout reported by the sensor 116 during rotation of the shaft carrier 104 when runout of the substrate support 212 carried by the shaft member 102 is within a predetermined amount), determine runout the substrate support 212 about the rotation axis 254 within the interior 242 (shown in FIG. 2) of the chamber body 220 (shown in FIG. 2) using the signal 172, and selectively increase the rotation current 168 and/or the levitation current 170 provided to individual windings (e.g., subsets) of the first plurality of windings 112 and/or the second plurality of windings 114 when the determined runout differs from the predetermined runout characterization by more than a predetermined amount. In accordance with the certain examples, the controller 208 may receive a predetermined wobble characterization of the substrate support 212 about the rotation axis 254 (e.g., wobble reported by the sensor 116 during rotation of the shaft carrier 104 when wobble of the substrate support 212 carried by the shaft member 102 is within a predetermined amount), determine wobble of the substrate support 212 about the rotation axis 254 within the interior 242 (shown in FIG. 2) of the chamber body 220 (shown in FIG. 2) using the signal 172, and selectively increase rotation current 168 and/or levitation current 170 provided to individual windings (e.g., subsets) of the first plurality of windings 112 and/or the second plurality of windings 114 when the determined wobble differs from the predetermined wobble characterization by more than a predetermined amount.

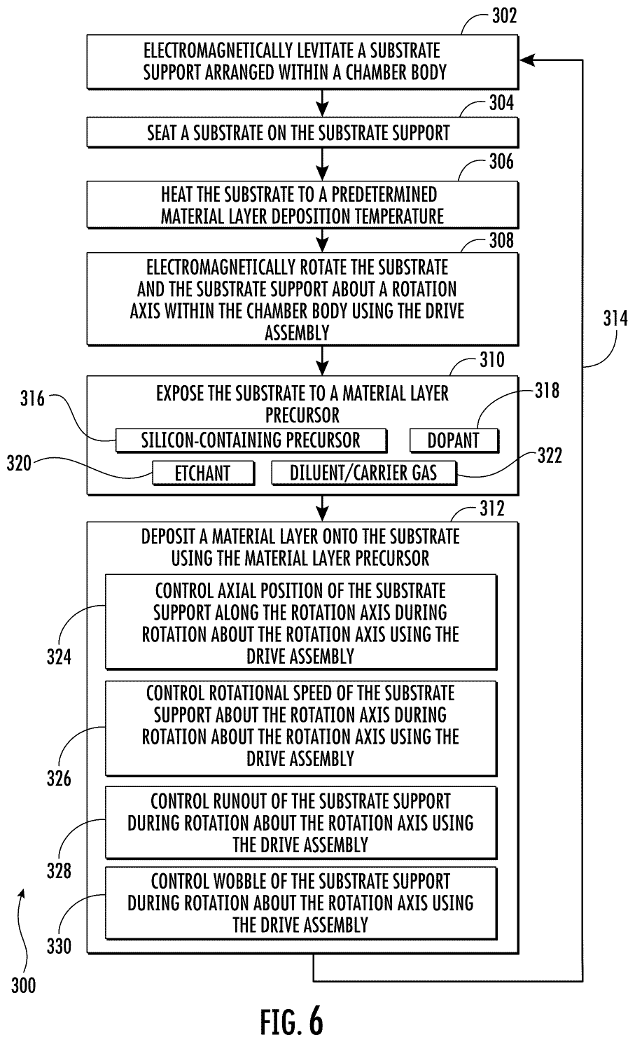

With reference to FIGS. 6-10, the material layer deposition method 300 is shown. As shown in FIG. 6, the material layer deposition method 300 may include electromagnetically levitating a substrate support arranged within a chamber body along a rotation axis using a drive assembly, e.g., levitating the substrate support 212 (shown in FIG. 2) within the chamber body 220 (shown in FIG. 2) along the rotation axis 254 (shown in FIG. 2), as shown with box 302. The material layer deposition method 300 may also include seating a substrate on the substrate support and within the chamber body, e.g., the substrate 2 (shown in FIG. 2), as shown with box 304. The material layer deposition method 300 may further include heating the substrate within the chamber body to a predetermined material layer deposition temperature and electromagnetically rotating about the rotation axis within the chamber body using the drive assembly, as shown with box 306 and box 308. The material layer deposition method 300 may additionally include exposing the substrate to a material layer precursor within the chamber body, e.g., exposing the substrate 2 (shown in FIG. 2) to the material layer precursor 10 (shown in FIG. 2), and depositing a material layer onto the substrate using the material layer precursor, e.g., depositing the material layer 4 (shown in FIG. 2) using the material layer precursor, as shown with box 310 and 312. As shown with arrow 314, the substrate may thereafter be removed from the chamber body such that a further material layer may be deposited onto a further substrate. A semiconductor device may be fabricated using the material layer deposited onto the substrate, such as a memory or logic device having a three-dimensional (3D) architecture. For example, a 3D DRAM device or a logic device having a gate-all-around architecture (GAA) may be formed using the material layer.

Electromagnetically levitating 302 the substrate support may include applying a levitation current to a second plurality of windings separated from the substrate support by a shaft carrier and a shaft member, e.g., the levitation current 170 (shown in FIG. 5) to the second plurality of windings 114 (shown in FIG. 3), as also shown with box 302. Electromagnetically levitating 302 the substrate support may include exerting an upwardly directed (relative to gravity) axial electromotive force on the shaft carrier using in cooperation with one or more permanent magnets seated in the shaft carrier, e.g., the one or more second permanent magnet 108 (shown in FIG. 3), as further shown with box 302. In certain examples the axial electromotive force may have substantially no off-axis force component, the axial electromotive force being directed only along the rotation axis, as also shown with box 302. In accordance with certain examples, the axial electromotive force may include an off-axis force component sized to limit at least one of runout and wobble of the substrate support during rotation within the chamber body about the rotation axis, as further shown with box 302. Electromagnetically levitating 302 the substrate support may be accomplished using instructions recorded in one or more of the plurality of program modules recorded on a memory of a controller, e.g., the plurality of program modules 268 (shown in FIG. 2) on the memory (shown in FIG. 2) of the controller 208 (shown in FIG. 2), as additionally shown with box 302.

Seating 304 the substrate on the substrate support may include opening a gate valve coupling a substrate transfer robot to the chamber body, e.g., the gate valve coupling the substrate transfer robot to the chamber body, and transferring a singular substrate into the chamber body, as shown also shown with box 304. The gate valve may thereafter be closed and rotation of the substrate support with the substrate thereon initiated, as further shown with box 304. Seating of the substrate—and unseating of the substrate subsequent to deposition of the material layer onto the substrate—may be accomplished using lift pins slidably received within the substrate support. Seating 304 of the substrate onto the substrate support may be accomplished using the controller, for example using instructions recorded in one or more of the plurality of program modules on the memory, as additionally shown with box 304.

Heating 306 the substrate to the predetermined material layer deposition temperature may include radiantly communicating heat into the interior of the chamber body, as also shown by box 306. Radiant heating may be accomplished by generating electromagnetic radiation within an infrared waveband from a heater element supported outside of the chamber body and transmitted through a ceramic material forming the chamber body, e.g., generated using the upper heater element array 226 (shown in FIG. 2) and/or the lower heater element array 228 (shown in FIG. 2) and transmitted through the ceramic material 236 (shown in FIG. 2) forming the chamber body, as further shown by box 306. Heating 306 the substrate within the chamber body may be accomplished using the controller, for example using instructions recorded in one or more of the plurality of program modules recorded on the memory of the controller, as additionally shown with box 306.

Electromagnetically rotating 308 the substrate support about the rotation axis may include applying a rotating current to a first plurality of windings distributed circumferentially about the shaft carrier of the drive assembly, e.g., applying the rotation current 168 (shown in FIG. 5) to the first plurality of windings 112 (shown in FIG. 3), as also shown with box 308. Electromagnetically rotating 308 the substrate support may include exerting a rotational electromotive force (e.g., a torque) on the shaft carrier via one or more first permanent magnet seated in the shaft carrier, e.g., one the one or more first permanent magnet 106 (shown in FIG. 3), as additionally shown with box 302. In certain examples the rotational electromotive force may have no out-of-plane component, i.e., no force component outside of a plane substantially orthogonal relative to the rotation axis, as also shown with box 308. In accordance with certain examples, the rotational electromotive force may have an out-of-plane component, as further shown with box 308. In such examples the out-of-plane component of the electromotive rotational force may be selected to limit (or eliminate) runout and/or wobble of the substrate support during rotation about the rotation axis, as further shown with box 308. Electromagnetically rotating 308 the substrate may be accomplished using the controller, for example using instructions recorded in one or more of the plurality of program modules recorded on the memory, as additionally shown with box 308.

Exposing 310 the substrate to the material layer precursor may include exposing the substrate to a silicon-containing material layer precursor, such as a non-chlorinated silicon-containing material layer precursor like silane (SiH₄) or disilane (Si₂H₆) and/or a chlorinated silicon-containing material layer precursor such as dichlorosilane (H₂SiCl₂) or trichlorosilane (HCl₃Si), as shown with box 316. Exposing 310 the substrate to the material layer precursor may include exposing the substrate to a dopant-containing material layer precursor or an alloying-containing material layer precursor, such as an n-type dopant-containing material layer precursor including arsine (As) or phosphorous (P) or a p-type dopant-containing material layer precursor including boron (B) as well as a germanium-containing material layer precursor lime germane (GeH₄), as shown with box 318. Exposing 310 the substrate to the material layer precursor may include exposing the substrate to an etchant, such a chlorinated etchant like hydrochloric (HCl) acid or chlorine (Cl₂) gas or a fluorinated composition like hydrofluoric (HF) acid, as shown with box 320. Exposing 310 the substrate to the material layer precursor may include co-flowing a carrier or diluent fluid with the material layer precursor, such as hydrogen (H₂) gas or nitrogen (N₂) gas, as shown with box 322. It is contemplated that exposing 310 the substrate to the material layer precursor may include exposing the substrate to a mixture including a silicon-containing material layer precursor, a dopant-containing material layer precursor, an etchant, and a carrier or diluent fluid, as also shown with box 310. It is also contemplated that exposing 310 the substrate to the material layer precursor may be accomplished using the controller, for example using instructions recorded in one or more of the plurality of program modules recorded on the memory, as additionally shown with box 310.

Depositing 312 the material layer onto the substrate may include depositing a material layer that is epitaxial with the substrate, as also shown with box 312. Depositing 312 the material layer may include depositing a silicon-containing material layer, such as an intrinsic silicon material layer or a silicon-germanium as well as a doped silicon-containing material layer, as further shown with box 312. Depositing 312 the material layer may include controlling axial position of the substrate support along the rotation axis during rotation of the substrate support about the rotation axis, as shown with box 324. Depositing 312 the material layer onto the substrate may include controlling rotational speed of the substrate support about the rotation axis during rotation about the rotation axis, as shown with box 326. Depositing 312 the material layer onto the substrate support may include controlling either (or both) runout and wobble of the substrate support within the chamber body during rotation of the substrate support about the rotation axis, as shown with box 328 and box 330. It is contemplated that controlling one or more of axial position, rotational position, runout, and wobble during deposition of the material layer may be controlled using the controller such as using instructions recorded in one or more of the plurality of program modules recorded on the memory, as also shown with boxes 324-330.

As shown in FIG. 7, controlling 324 axial position of the substrate support within the chamber body may include receiving a signal indicative of axial position of the substrate support within the chamber body along the rotation axis, e.g., the signal 172 (shown in FIG. 5), as shown with box 332. Axial position of the substrate support may be determined using the information indicative of axial position of the substrate support along the rotation axis, for example using the controller, as shown with box 334. The determined axial position be compared to a predetermined axial position value, for example a predetermined axial position valve received at the user interface 264 (shown in FIG. 2), as shown with box 336. The axial position of the substrate support may be adjusted when the comparison indicates that axial height of the substrate support differs from the predetermined axial value by more than a predetermined amount, as shown with boxes 338 and 342 and arrow 340. Adjustment of axial position of the substrate support may be accomplished by throttling the levitation current provided to the second plurality of windings, as shown with box 344. Adjustment of axial position of the substrate support may be accomplished in real-time with receipt of the signal containing the information indicative of axial position of the substrate support along the rotation axis and/or during deposition of the material layer onto the substrate, as shown with box 346. Monitoring of axial position of the substrate support may thereafter continue, such as iteratively during deposition of the material layer onto the substrate, as shown with arrow 348. When the determined axial position does not differ from the predetermined axial height by more than the predetermined value no adjustment to axial height of the substrate support may be made, as shown with arrow 350.

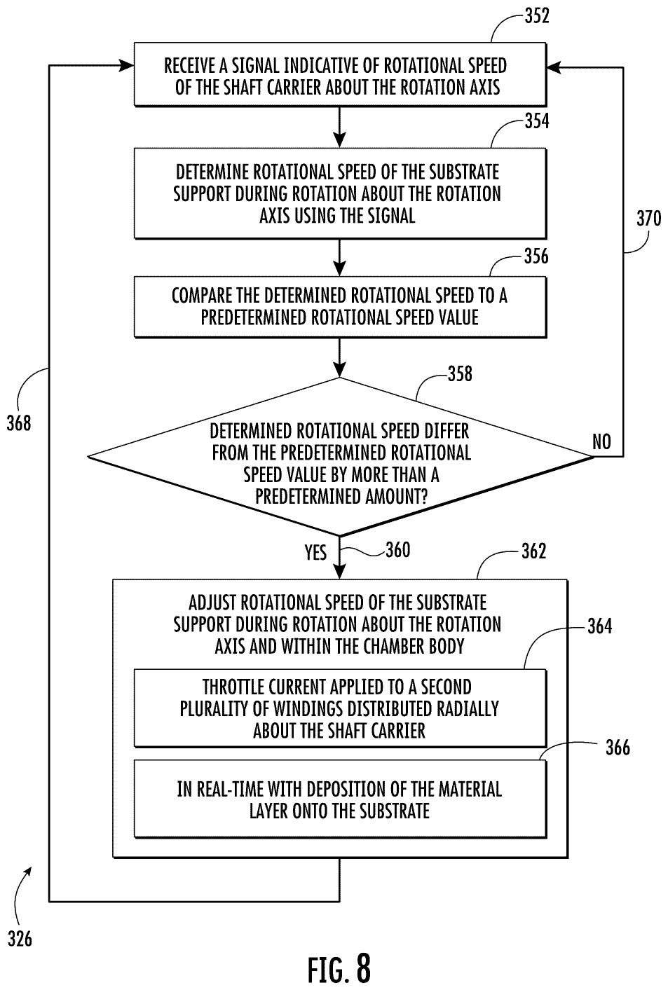

As shown in FIG. 8, controlling 326 rotational speed of the substrate support during rotation about the rotation axis and within the chamber body may include receiving a signal indicative of rotational speed of the substrate support within the chamber body during rotation about the rotation axis, e.g., the signal 172 (shown in FIG. 5), as shown with box 352. Rotational speed of the substrate support may be determined using the information indicative of the rotational speed of the substrate support during rotation about the rotation axis, for example using the controller, as shown with box 354. It is contemplated that the determined rotational speed may be compared to a predetermined rotational speed, for example a predetermined rotation speed value received at the user interface, as shown with box 356, and rotational speed of the substrate support may be adjusted when the determined rotational speed of the substrate support differs from the predetermined rotational speed value by more than a predetermined amount, as shown with boxes 358 and 362 and arrow 360. Adjustment of rotational speed of the substrate support may be accomplished by throttling the rotational current provided to the first plurality of windings, as shown with box 364. Adjustment of rotational speed of the substrate support may be accomplished in real-time with receipt of the signal containing the information indicative of rotational speed of the substrate support about the rotation axis and/or during deposition of the material layer onto the substrate, as shown with box 366. It is contemplated that monitoring of rotational speed of the substrate support may continue after the aforementioned adjustment, such as iteratively during deposition of the material layer onto the substrate, as shown with arrow 368. It is also contemplated that no adjustment may be made to rotational speed of the substrate support when the determined rotational speed does not differ from the predetermined rotational speed value by more than the predetermined value, as shown with arrow 370.

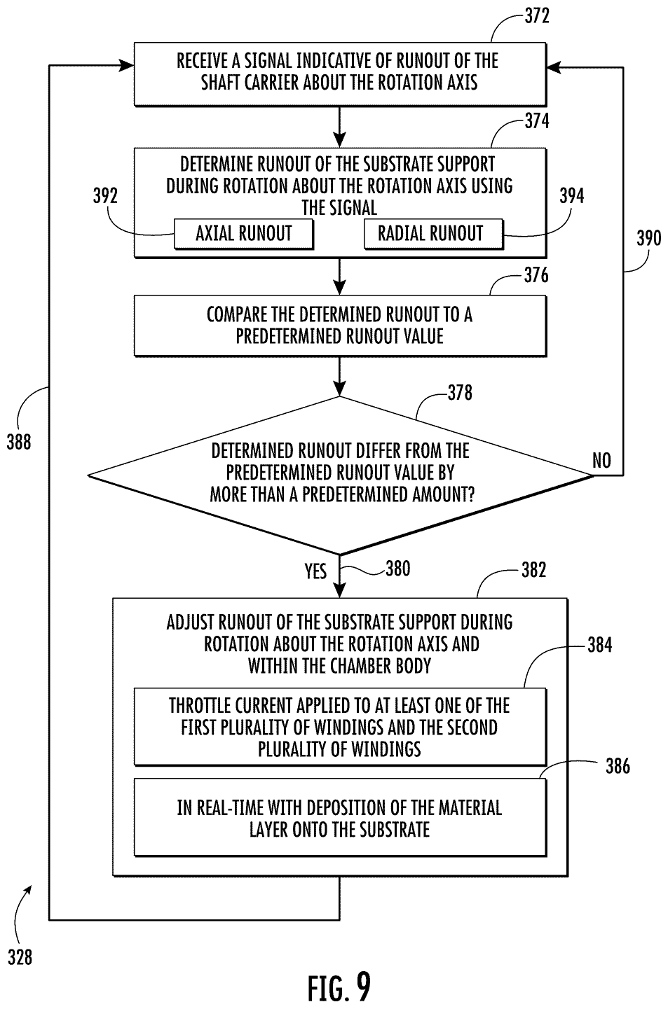

As shown in FIG. 9, controlling 328 runout of the substrate support during rotation about the rotation axis and within the chamber body may include receiving a signal indicative of runout of the substrate support within the chamber body during rotation about the rotation axis, e.g., the signal 172 (shown in FIG. 5), as shown with box 372. Runout of the substrate support may be determined using the information indicative of runout of the substrate support during rotation about the rotation axis, for example using the controller, as shown with box 374. The determined runout may be compared to a predetermined runout value, for example a predetermined runout value received at the user interface, as shown with box 376, and runout of the substrate support may be adjusted when the determined runout of the substrate support differs from the predetermined runout value by more than a predetermined amount, as shown with boxes 378 and 382 and arrow 380. Adjustment of the runout of the substrate support may be accomplished by throttling either (or both) the levitation rotational current provided to individual one of the first plurality of windings and the second plurality of windings, as shown with box 384. Adjustment of the runout of the substrate support may be accomplished in real-time with receipt of the signal containing the information indicative of runout of the substrate support during rotation about the rotation axis and/or during deposition of the material layer onto the substrate, as shown with box 386. It is contemplated that monitoring of runout of the substrate support may continue after the aforementioned runout adjustment, such as iteratively during deposition of the material layer onto the substrate, as shown with arrow 388. It is also contemplated that no adjustment may be made to runout of the substrate support when the determined runout does not differ from the predetermined runout value by more than the predetermined value, as shown with arrow 390. In certain examples adjusting runout may include adjusting axial runout, as shown with box 392. In accordance with certain examples, adjusting runout may include adjusting radial runout, as shown with box 394.

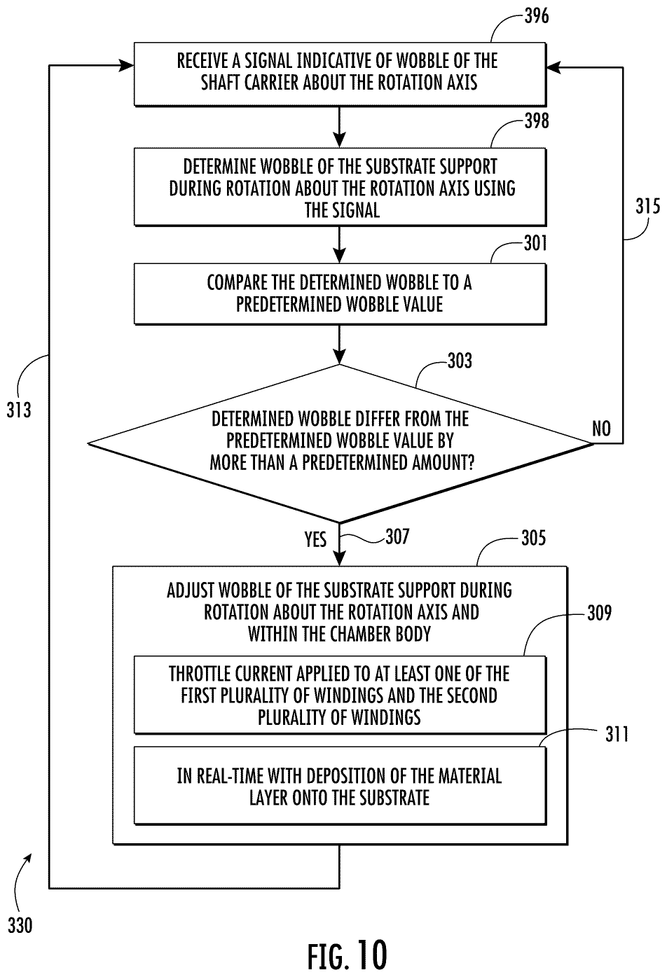

As shown in FIG. 10, controlling 330 wobble of the substrate support during rotation about the rotation axis and within the chamber body may include receiving a signal indicative of wobble of the substrate support within the chamber body during rotation about the rotation axis, e.g., the signal 172 (shown in FIG. 5), as shown with box 396. Wobble of the substrate support may be determined using the information indicative of wobble of the substrate support during rotation about the rotation axis, for example using the controller, as shown with box 398. The determined runout may be compared to a predetermined wobble value, for example a predetermined wobble value received the user interface, as shown with box 301, and wobble of the substrate support may be adjusted when the determined wobble of the substrate support differs from the predetermined wobble value by more than a predetermined amount, as shown with boxes 303-305 and arrow 307. Adjustment of the wobble of the substrate support may be accomplished by throttling either (or both) the levitation rotational current provided to individual one of the first plurality of windings and the second plurality of windings, as shown with box 309. Adjustment of the wobble of the substrate support may be accomplished in real-time with receipt of the signal containing the information indicative of wobble of the substrate support during rotation about the rotation axis and/or during deposition of the material layer onto the substrate, as shown with box 311. It is contemplated that monitoring of wobble of the substrate support may continue after the aforementioned wobble adjustment, such as iteratively during deposition of the material layer onto the substrate, as shown with arrow 313. It is also contemplated that no adjustment may be made to wobble of the substrate support when the determined wobble does not differ from the predetermined wobble value by more than the predetermined value, as shown with arrow 315.

Substrate supports may be rotated using direct-drive arrangements, such as using gear arrangements and transmission assemblies coupling a rotation source to the substrate support. While generally acceptable for their intended purpose, such direct-drive arrangements add cost and complexity to semiconductor processing systems. For example, direct drive arrangements may require relatively tight manufacturing and assembly tolerances to components coupling the rotation source to the substrate support, potentially limiting throughput of the semiconductor processing system and/or requiring highly skilled maintainers and service personnel.

In examples described herein an electromagnetic drive assembly is coupled to a substrate support in a semiconductor processing system. In certain examples of the present disclosure the drive assembly may electromagnetically levitate the substrate support along a rotation axis within a chamber body of the semiconductor processing system. In accordance with certain examples, the drive assembly may electromagnetically levitate the substrate support along the rotation axis and within the chamber body of the semiconductor processing system. It is also contemplated that, in accordance with certain examples, the substrate support may be both electromagnetically rotated about the rotation axis and electromagnetically levitated along the rotation axis within the chamber body of the semiconductor processing system. In further examples of the present disclosure, either (or both) of runout and wobble of the substrate support during rotation about the rotation axis and within the chamber body of the semiconductor processing system may be electromagnetically controlled using the drive assembly. Advantageously, examples of the drive assembly described herein may simplify fabrication and/or increase throughput of semiconductor processing systems by relaxing manufacturing and/or assembly tolerances of elements coupling the substrate support to the drive assembly.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A drive assembly, comprising:
a shaft member with a spider end and a drive end arranged along a rotation axis;
a shaft carrier seating therein the drive end of the shaft member and fixed in rotation about the rotation axis relative to the shaft member; and
a permanent magnet seated in the shaft carrier and fixed in rotation about the rotation axis relative to the shaft carrier,
wherein the permanent magnet is axially offset from the spider end of the shaft member to at least one of electromagnetically levitate and electromagnetically rotate a substrate support carried on the spider end of the shaft member.

2. The drive assembly of claim 1, wherein the shaft carrier has:
a first surface extending about the rotation axis and defining a shaft seat therein;
a second surface extending about the rotation axis and axially offset from the first surface of the shaft carrier; and
an intermediate surface extending about the rotation axis and coupling the first surface of the shaft carrier to the second surface of the shaft carrier, wherein the second surface tapers between a major radial width proximate the intermediate surface and a minor radial width axially opposite the first surface of the shaft carrier.

3. The drive assembly of claim 2, wherein the permanent magnet is arranged axially between the first surface and the second surface of the shaft carrier to electromagnetically rotate the shaft carrier and therethrough the substrate support in rotation about the rotation axis.

4. The drive assembly of claim 2, wherein the permanent magnet is arranged axially between the major radial width and the minor radial width defined by the shaft carrier to electromagnetically levitate the shaft carrier and therethrough the substrate support along the rotation axis.

5. The drive assembly of claim 1, further comprising a sensor opposing the shaft carrier and configured to acquire at least one of axial position of the substrate support along the rotation axis and rotational position of the substrate support during rotation about the rotation axis.

6. The drive assembly of claim 1, further comprising a stator body extending about the shaft carrier, the stator body formed from a non-magnetic material, the stator body having a hollow interior terminating at a tapered recess, the stator body receiving the shaft carrier within the hollow interior of the stator body.

7. The drive assembly of claim 1, further comprising a plurality of windings distributed circumferentially about the rotation axis, wherein the plurality of windings the one or more permanent magnet inhabit a common axial position.

8. The drive assembly of claim 1, further comprising a plurality of windings axially overlapped by the shaft carrier.

9. The drive assembly of claim 8, wherein the plurality of windings is at least one of (a) arranged in a grid and (b) distributed about a circumference overlayed by the shaft carrier.

10. The drive assembly of claim 1, wherein the shaft member comprises a ceramic material.

11. A semiconductor processing system, comprising:
a chamber body having a hollow interior;
a drive assembly as recited in claim 1, wherein the shaft member extends into the chamber body such that the spider end of the shaft member is disposed within the interior of the chamber body; and
a substrate support arranged within the interior of the chamber body and fixed in rotation about the rotation axis relative to the shaft member of the drive assembly; and
a controller operatively connected to the drive assembly and responsive to instructions record on a memory:
electromagnetically levitate the substrate support within the interior of the chamber body and along the rotation axis using the drive assembly; and
electromagnetically rotate the substrate support within the interior of the chamber body and about the rotation axis using the drive assembly.

12. The semiconductor processing system of claim 11, wherein the permanent magnet is a first permanent magnet arranged axially between a first surface and a second surface of the shaft carrier, wherein the drive assembly further comprises:
a second permanent magnet fixed in the shaft carrier and arranged axially between a major radial width and a minor radial width defined by the shaft carrier;
a first plurality of windings radially offset from the shaft carrier and configured to electromagnetically exert a rotational force on the shaft carrier via the first permanent magnet;
a second plurality of windings axially offset from the shaft carrier and configured to electromagnetically exert an axial force on the shaft carrier via the second permanent magnet;
wherein the instructions recorded on the memory cause the controller to:
electromagnetically rotate the substrate support using the one or more first permanent magnet and a rotation current provided to the second plurality of windings; and
electromagnetically levitate the substrate support using the one or more second permanent magnet and a levitation current provided to the first plurality of windings.

13. The semiconductor processing system of claim 11, further comprising a sensor disposed in communication with the shaft carrier and configured to provide a signal to the controller indicative of at least one of an axial position and a rotational position of the substrate support within the chamber body.

14. The semiconductor processing system of claim 13, wherein the instructions further cause the controller to control at least one of axial position of the substrate support along the rotation axis and rotational speed of the substrate support about the rotation axis within the chamber body using the signal provided by the sensor.

15. The semiconductor processing system of claim 13, wherein the instructions further cause the controller to control at least one of runout and wobble of the substrate support within the chamber body during rotation about the rotation axis using the signal provided by the sensor.

16. A method of depositing a material layer onto a substrate, comprising:
at a semiconductor processing system including a substrate support arranged within an interior of a chamber body and seated on a drive assembly including a shaft member with a spider end and a drive end arranged along a rotation axis; a shaft carrier seating therein the drive end of the shaft member and fixed in rotation about the rotation axis relative to the shaft member; and a permanent magnet seated in the shaft carrier, fixed in rotation about the rotation axis relative to the shaft carrier, and axially offset from the spider end of the shaft member along the rotation axis;
seating a substrate on the substrate support; and
while at least one of electromagnetically levitating the substrate support and electromagnetically rotating the substrate support using the permanent magnet and a plurality of windings electromagnetically coupled to the permanent magnet,
heating the substrate to a predetermined material layer deposition temperature;
exposing the substrate to a material layer precursor; and
depositing a material layer onto the substrate using the material layer precursor.

17. The material layer deposition method of claim 16, further comprising:
determining axial position of the substrate support along the rotation axis during rotation about the rotation axis;
comparing the determined axial position to a predetermined axial position; and
adjusting axial height of the substrate support when the determined axial position differs from the predetermined axial position by more than a predetermined amount during deposition of the material layer onto the substrate.

18. The material layer deposition method of claim 16, further comprising:
determining rotational speed of the substrate support about the rotation axis during rotation about the rotation axis;
comparing the determined rotational speed of the substrate support to a predetermined rotational speed; and
adjusting rotational speed of the substrate support when the determined rotational speed differs from the predetermined rotational speed by more than a predetermined amount during deposition of the material layer onto the substrate.

19. The material layer deposition method of claim 16, further comprising:
determining runout of the substrate support about the rotation axis during rotation about the rotation axis;
comparing the determined runout of the substrate support to a predetermined runout value; and
adjusting runout of the substrate support when the determined runout differs from the predetermined runout value by more than a predetermined amount during deposition of the material layer onto the substrate.

20. The material layer deposition method of claim 16, further comprising:
determining wobble of the substrate support about the rotation axis during rotation about the rotation axis;
comparing the determined wobble of the substrate support to a predetermined wobble value; and
adjusting wobble of the substrate support when the determined wobble differs from the predetermined wobble value by more than a predetermined amount during deposition of the material layer onto the substrate.
